(19) United States
(12) Patent Application Publication
(10) Pub. No.: US 2015/0243516 A1
(43) Pub. Date: Aug. 27, 2015

(54) Semiconductor Device And Manufacturing Method Of The Same

(71) Applicant: TOYODA GOSEI CO., LTD., Kiyosu-shi (JP)

(72) Inventors: Tsutomu INA, Kiyosu-shi (JP); Tohru OKA, Kiyosu-shi (JP)

(21) Appl. No.: 14/616,574

(22) Filed: Feb. 6, 2015

(30) Foreign Application Priority Data
Feb. 21, 2014 (JP) 2014-031811

(51) Int. Cl. H01L 21/306; H01L 21/308; H01L 29/20; H01L 29/66; H01L 29/78; H01L 29/423

(52) U.S. Cl. CPC H01L 21/30604; H01L 29/7827; H01L 29/4236; H01L 29/2003; H01L 29/66666; H01L 21/3081

(57) ABSTRACT

An object is to improve the electrical characteristics of a semiconductor device. A semiconductor device using a hexagonal semiconductor is provided. The semiconductor device comprises a semiconductor substrate, a first N-type semiconductor layer formed on the semiconductor substrate, a P-type semiconductor layer formed on the first N-type semiconductor layer, a second N-type semiconductor layer formed on the P-type semiconductor layer, and a trench concaved to pass through the second N-type semiconductor layer and the P-type semiconductor layer and reach the first N-type semiconductor layer. The trench is arranged to have a longitudinal direction thereof at right angle ±15 degrees to an [11-20] axis and has concavity/convexity in a striped pattern formed on a side wall of the trench to be at right angle to a [0001] axis.

### CROSS-REFERENCE TO RELATED APPLICATION

The present application claims priority from Japanese patent applications No. 2014-31811 filed on Feb. 21, 2014, the entirety of disclosures of which is hereby incorporated by reference into this application.

### TECHNICAL FIELD

The present invention relates to a semiconductor device.

### DESCRIPTION OF THE RELATED ART

Known techniques employed for a semiconductor device perform wet etching after dry etching, in order to suppress leak current and improve electrical characteristics of the semiconductor device (for example, JP 2010-62381A and JP 2010-40697A).

### SUMMARY

These proposed techniques, however, enable the layer damaged by dry etching to be removed by wet etching but do not sufficiently improve the electrical characteristics. There is accordingly a need to provide a method of more effectively improving the electrical characteristics. Other needs in the prior art semiconductor device include downsizing, resource saving, easy manufacture, accuracy of manufacture and improvement of workability.

In order to solve at least part of the problems described above, the invention may be implemented by aspects described below.

(1) According to one aspect of the invention, there is provided a semiconductor device using a hexagonal semiconductor. The semiconductor device comprises: a semiconductor substrate; a first N-type semiconductor layer formed on the semiconductor substrate; a P-type semiconductor layer formed on the first N-type semiconductor layer; a second N-type semiconductor layer formed on the P-type semiconductor layer; and a trench concaved to pass through the second N-type semiconductor layer and the P-type semiconductor layer and reach the first N-type semiconductor layer, wherein the trench is arranged to have a longitudinal direction thereof at right angle ±15 degrees to an [11-20] axis and has concavity/convexity in a striped pattern formed on a side wall of the trench to be at right angle to a [0001] axis. The configuration of this aspect increases the surface area of the side wall of the trench, compared with a configuration without concavity/convexity on the surface wall of the trench. As a result, this improves the electrical characteristics of the semiconductor device. For example, when the semiconductor device is a vertical MOSFET, this configuration enhances the current density between the source and the drain per element of the semiconductor device.

(2) According to one embodiment, the semiconductor device of the above aspect may further comprise an electrode formed in the trench via an insulating film. This configuration improves the electrical characteristics in the trench having the electrode formed via the insulating film.

(3) According to one embodiment of the semiconductor device of any of the above aspect, the semiconductor device may be MOSFET. This configuration further improves the electrical characteristics of the semiconductor device.

(4) According to one embodiment of the semiconductor device of any of the above aspect, each side of the concavity/convexity perpendicular to the [0001] axis may have a length of not less than 10 nm and not greater than 200 nm. This configuration improves the electrical characteristics of the semiconductor device without excessive etching, while suppressing an increase in manufacturing cost.

(5) According to one embodiment of the semiconductor device of any of the above aspect, the side wall of the trench with the concavity/convexity may have a surface area of 1.1 times or more of a surface area of a side wall of a trench without the concavity/convexity. As a result, this configuration improves the electrical characteristics of the semiconductor device.

(6) According to one embodiment of the semiconductor device of any of the above aspect, the side wall of the trench may have an angle of 90 degrees to 95 degrees relative to a bottom surface of the trench. This configuration suppresses the potential crowding on the bottom surface of the trench, thus improving the breakdown voltage of the semiconductor device.

(7) According to one embodiment of the semiconductor device of any of the above aspect, the concavity/convexity on the side wall of the trench may have a height between a bottom of the concavity and a top of the convexity of 5% or less of a cell pitch. This configuration reduces the ratio of the concavity/convexity occupied in the semiconductor device, thus allowing for miniaturization of the semiconductor device.

(8) According to one embodiment of the semiconductor device of any of the above aspect, the semiconductor may be mainly made of gallium nitride.

(9) According to another aspect of the invention, there is provided a manufacturing method of a semiconductor device using a hexagonal semiconductor. the manufacturing method of the semiconductor device comprises: providing an intermediate product of the semiconductor device having a semiconductor substrate, a first N-type semiconductor layer formed on the semiconductor substrate, a P-type semiconductor layer formed on the first N-type semiconductor layer, and a second N-type semiconductor layer formed on the P-type semiconductor layer; patterning a photoresist on the second N-type semiconductor layer, such that a longitudinal direction of patterning is at right angle ±15 degrees to an [11-20] axis; after the patterning, forming a trench concaved to pass through the second N-type semiconductor layer and the P-type semiconductor layer and reach the first N-type semiconductor layer by dry etching; and after the forming the trench, forming concavity/convexity on a side wall of the trench by wet etching. The manufacturing method of this aspect improves the electrical characteristics of the semiconductor device.

All the plurality of components included in the aspect of the invention described above are not essential, but some components among the plurality of components may be appropriately changed, omitted or replaced with other components or part of the limitations may be deleted, in order to solve part or all of the problems described above or in order to achieve part or all of the advantageous effects described herein. In order to solve part or all of the problems described above or in order to achieve part or all of the advantageous effects described herein, part or all of the technical features included in one aspect of the invention described above may be combined with part or all of the technical features included in another aspect of the invention described later to provide still another independent aspect of the invention.

The invention may be implemented by any of various aspects other than the semiconductor device and the manufacturing method thereof: for example, an electrical apparatus including the semiconductor device of any of the above aspects and a manufacturing apparatus for manufacturing the semiconductor device of any of the above aspects.

The semiconductor device of the above aspect has the increased surface area of the side wall of the trench, compared with the configuration without concavity/convexity on the side wall of the trench. As a result, this improves the electrical characteristics of the semiconductor device. For example, when the semiconductor device is a vertical MOSFET, this configuration enhances the current density between the source and the drain per element of the semiconductor device.

### BRIEF DESCRIPTION OF DRAWINGS

FIG. 1 is a cross sectional view schematically illustrating the structure of a semiconductor device according to a first embodiment;

FIG. 2 is a flowchart showing a manufacturing method of the semiconductor device;

FIG. 3 is a cross sectional view illustrating an intermediate product of the semiconductor device;

FIG. 4 is a cross sectional view illustrating the intermediate product of the semiconductor device having recesses;

FIG. 5 is a cross sectional view illustrating the intermediate product of the semiconductor device having an insulating film and a photoresist placed thereon;

FIG. 6 is a cross sectional view illustrating the intermediate product of the semiconductor device having an N-type semiconductor layer partly exposed;

FIG. 7 is a cross sectional view illustrating the intermediate product of the semiconductor device after dry etching;

FIG. 8 is diagrams illustrating the intermediate product of the semiconductor device in the states before and after wet etching;

FIG. 9 is an enlarged view illustrating a side wall of a trench;

FIG. 10 is a cross sectional view illustrating the intermediate product of the semiconductor device after removal of the insulating film;

FIG. 11 is a cross sectional view illustrating the intermediate product of the semiconductor device having electrodes formed thereon;

FIG. 12 is a graph showing the ratio of Id to Id of a semiconductor device without concavity/convexity on a side wall which is set equal to 1 as an average, in Id-Vg measurement of a semiconductor device with concavity/convexity on the side wall and the semiconductor device without concavity/convexity on the side wall; and

FIG. 13 is a cross sectional view illustrating another semiconductor device having a body electrode and a source electrode formed in partly overlapping state.

### DESCRIPTION OF EMBODIMENTS

### A. First Embodiment

A1. Structure of Semiconductor Device 10

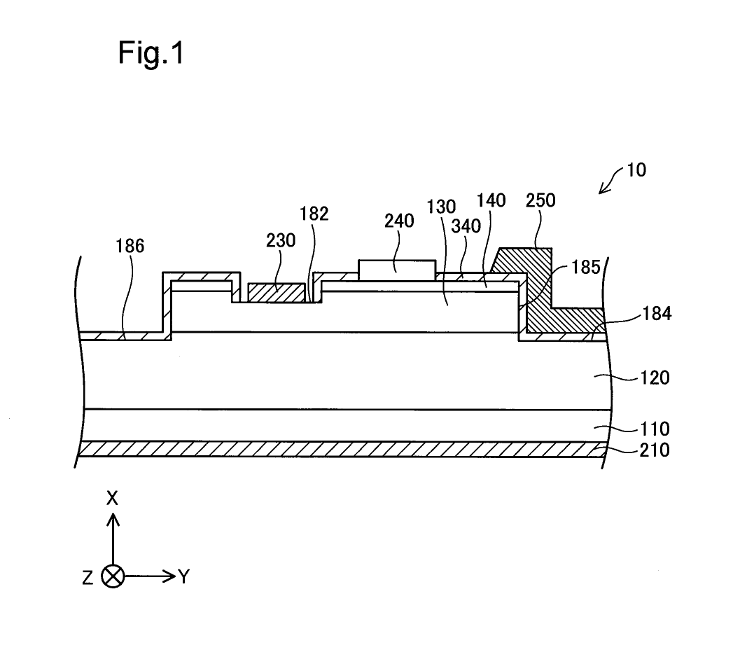

FIG. 1 is a cross sectional view schematically illustrating the structure of a semiconductor device 10 according to a first embodiment. The semiconductor device 10 is a GaN-based semiconductor device formed by using gallium nitride (GaN). According to this embodiment, the semiconductor device 10 is a trench gate-type MOSFET (metal oxide semiconductor field effect transistor) used for power control and is also called power device.

The semiconductor device 10 includes a substrate 110, an N-type semiconductor layer 120, a P-type semiconductor layer 130, another N-type semiconductor layer 140, electrodes 210, 230, 240 and 250 and an insulating film 340. The semiconductor device 10 is an NPN-type semiconductor device having the structure that the N-type semiconductor layer 120, the P-type semiconductor layer 130 and the N-type semiconductor layer 140 are sequentially joined with one another. The “substrate 110” is also called “semiconductor substrate 110”; the “N-type semiconductor layer 120” is also called “first N-type semiconductor layer 120”; and the “N-type semiconductor layer 140” is also called “second N-type semiconductor layer 140”.

The N-type semiconductor layer 120, the P-type semiconductor layer 130 and the N-type semiconductor layer 140 of the semiconductor device 10 are semiconductor layers formed by crystal growth according to the metal organic chemical vapor deposition (MOCVD). The semiconductor device 10 has a recess 182, a trench 184 and a recess 186 formed by dry etching.

XYZ axes orthogonal to one another are shown in FIG. 1. Among the XYZ axes of FIG. 1, X axis is an axis along a stacking direction in which the N-type semiconductor layer 120 is stacked on the substrate 110. With respect to X-axis direction along the X axis, +X-axis direction denote a direction from the substrate 110 toward the N-type semiconductor layer 120, and −X-axis direction denotes a direction reverse to the +X-axis direction. Among the XYZ axes of FIG. 1, Y axis and Z axis are respectively orthogonal to the X axis and are also orthogonal to each other. With respect to Y-axis direction along the Y axis, +Y-axis direction denotes a direction from the left side toward the right side of the sheet surface of FIG. 1, and −Y-axis direction denotes a direction reverse to the +Y-axis direction. With respect to Z-axis direction along the Z axis, +Z-axis direction denotes a direction from the front side toward the rear side of the sheet surface of FIG. 1, and −Z-axis direction denotes a direction reverse to the +Z-axis direction. According to this embodiment, the X axis is [0001] axis, the Y axis is [11-20] axis and the Z-axis is [1-100] axis.

The substrate 110 of the semiconductor device 10 is a semiconductor layer extended along a planar direction defined by the Y axis and the Z axis. According to this embodiment, the substrate 110 is mainly made of gallium nitride (GaN) and contains N-type impurity such as germanium (Ge), oxygen (O) or silicon (Si) as donor at the higher concentration than that in the N-type semiconductor layer 120. Being mainly made of gallium nitride (GaN) means containing 90% or more of gallium nitride (GaN) at the molar fraction.

The N-type semiconductor layer 120 of the semiconductor device 10 is a semiconductor layer stacked on the +X-axis direction side of the substrate 110 and extended along the planar direction defined by the Y axis and the Z axis. The N-type semiconductor layer 120 is mainly made of gallium nitride (GaN) and contains silicon (Si) as donor at the lower concentration than that in the N-type semiconductor layer 140. The N-type semiconductor layer 120 is also called “n⁻-GaN”.

The P-type semiconductor layer 130 of the semiconductor device 10 is a semiconductor layer stacked on the +X-axis direction side of the N-type semiconductor layer 120 and extended along the planar direction defined by the Y axis and the Z axis. The P-type semiconductor layer 130 is mainly made of gallium nitride (GaN) and contains magnesium (Mg) as P-type impurity. The P-type semiconductor layer 130 is also called “p-GaN”.

The N-type semiconductor layer 140 of the semiconductor device 10 is a semiconductor layer stacked on the +X-axis direction side of the P-type semiconductor layer 130 and extended along the planar direction defined by the Y axis and the Z axis. The N-type semiconductor layer 140 is mainly made of gallium nitride (GaN) and contains silicon (Si) as donor at the higher concentration than that in the N-type semiconductor layer 120. The N-type semiconductor layer 140 is also called “n+-GaN”.

The recess 182 of the semiconductor device 10 is formed by dry etching as an area concaved from the +X-axis direction side of the N-type semiconductor layer 140 to expose the P-type semiconductor layer 130.

The trench 184 of the semiconductor device 10 is formed by dry etching as an area concaved from the +X-axis direction side of the N-type semiconductor layer 140 to pass through the P-type semiconductor layer 130 and reach the N-type semiconductor layer 120. According to this embodiment, the trench 184 is located on the +Y-axis direction side of the recess 182.

The insulating film 340 is formed on the surface of the trench 184 to the +X-axis direction side of the N-type semiconductor layer 140. According to this embodiment, the insulating film 340 is made of silicon dioxide (SiO2).

The recess 186 of the semiconductor device 10 is formed by dry etching as an area concaved from the +X-axis direction side of the N-type semiconductor layer 140 to pass through the P-type semiconductor layer 130 and reach the N-type semiconductor layer 120. The recess 186 is an area provided for separation of the semiconductor element. According to this embodiment, the recess 186 is located on the −Y-axis direction side of the trench 184.

The electrode 210 of the semiconductor device 10 is a drain electrode formed on the −X-axis direction side of the substrate 110. According to this embodiment, the electrode 210 is formed by stacking a layer made of aluminum (Al) on a layer made of titanium (Ti) and annealing the stacked layers.

The electrode 230 of the semiconductor device 10 is a body electrode formed on the P-type semiconductor layer 130 exposed inside of the recess 182. According to this embodiment, the electrode 230 is formed by providing and annealing a layer made of palladium (Pd).

The electrode 240 of the semiconductor device 10 is a source electrode formed on the +X-axis direction side of the N-type semiconductor layer 140 between the recess 182 and the trench 184. According to this embodiment, the electrode 240 is formed by stacking a layer made of aluminum (Al) on a layer made of titanium (Ti) and annealing the stacked layers.

The electrode 250 of the semiconductor device 10 is a gate electrode formed on the insulating film 340 in the trench 184. According to this embodiment, the electrode 250 is made of aluminum (Al).

The trench 184 has concavity/convexity on its side wall 185. The concavity/convexity is formed through the manufacturing process described later in detail. The concavity/convexity is striped concavity/convexity perpendicular to the [0001] axis and is extended along the X-axis direction. Providing such concavity/convexity increases the surface area per unit area of the side wall 185. This configuration improves the electrical characteristics of the semiconductor device. More specifically, this enhances the current density between the source and drain electrodes per element of the semiconductor device.

A2. Manufacturing Method of Semiconductor Device 10

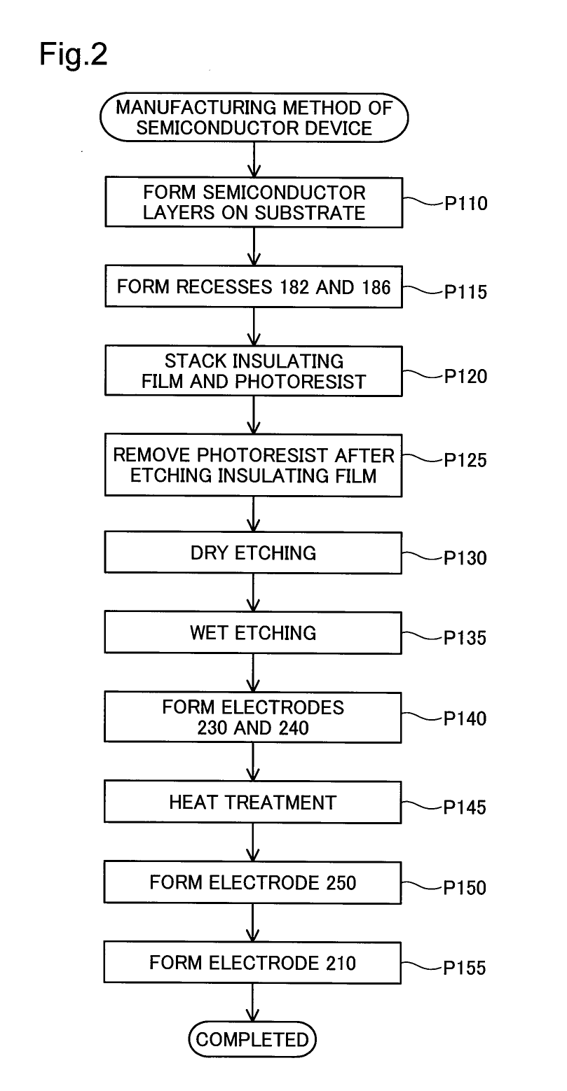

FIG. 2 is a flowchart showing a manufacturing method of the semiconductor device 10. In the process of manufacturing the semiconductor device 10, the manufacturer sequentially forms the N-type semiconductor layer 120, the P-type semiconductor layer 130 and the N-type semiconductor layer 140 on the substrate 110 (step P110). The manufacturer accordingly obtains an intermediate product of the semiconductor device 10 in which the respective semiconductor layers are formed on the substrate 110. In other words, the manufacturer provides the intermediate product of the semiconductor device 10 at step P110. The intermediate product herein means a semiconductor device in the course of manufacture.

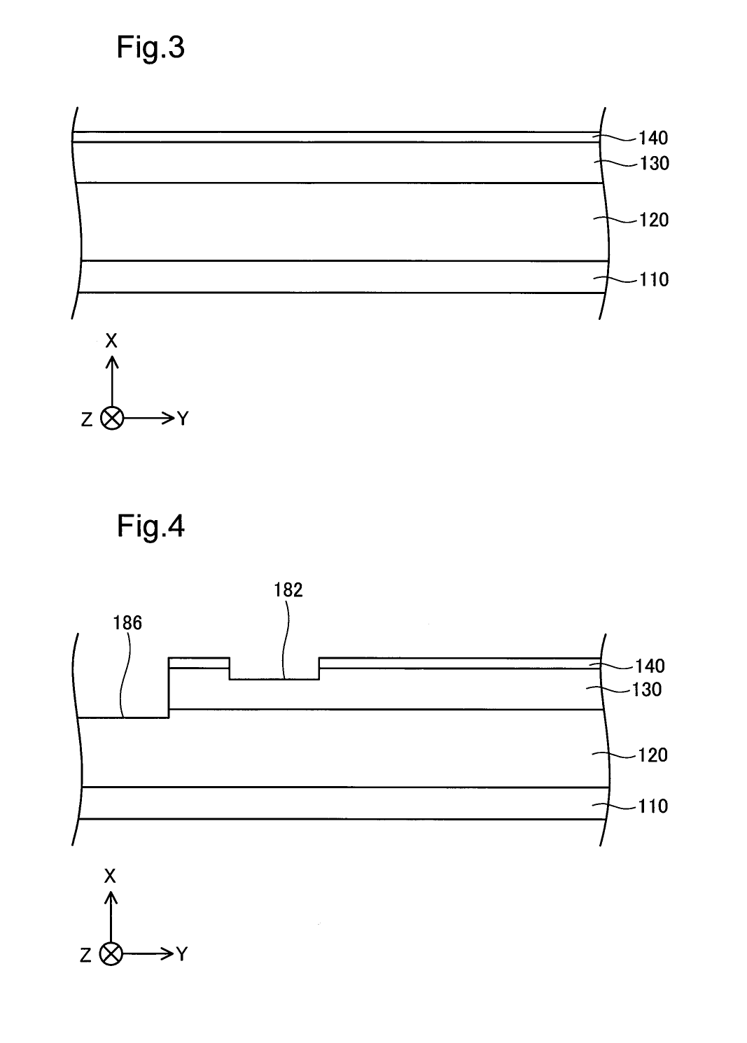

FIG. 3 is a cross sectional view illustrating the intermediate product of the semiconductor device 10. According to this embodiment, the manufacturer forms the respective semiconductor layers on the substrate 110 by metal organic chemical vapor deposition (MOCVD).

After forming the respective semiconductor layers, the manufacturer forms the recess 182 concaved from the N-type semiconductor layer 140 to reach the P-type semiconductor layer 130 and the recess 186 concaved from the N-type semiconductor layer 140 to reach the N-type semiconductor layer 120 in the intermediate product of the semiconductor device 10 (step P115).

FIG. 4 is a cross sectional view illustrating the intermediate product of the semiconductor device 10 having the recess 182 and the recess 186. A process of forming the recess 182 and the recess 186 places an insulating film as a mask and patterns a photoresist. The longitudinal direction of patterning for the recess 182 and the recess 186 may not be necessarily at right angle to the [11-20] axis. The manufacture then performs etching to form the recess 182 and the recess 186. This embodiment employs dry etching. After dry etching, wet etching may be performed additionally to remove the layer damaged by etching.

Subsequently, in order to form the trench 184 concaved from the N-type semiconductor layer 140 to reach the N-type semiconductor layer 120 in the intermediate product of the semiconductor device 10, the manufacturer stacks an insulating film 300 as a mask on the surface (+X-axis direction side face) of the intermediate product and then patterns a photoresist 400 (step P120). Patterning should be performed, such that the longitudinal direction of patterning is at right angle ±15 degrees to the [11-20] axis. The longitudinal direction of patterning is Z-axis direction in the illustration. The patterning angle may be controlled, for example, based on the orientation flat of the substrate 110.

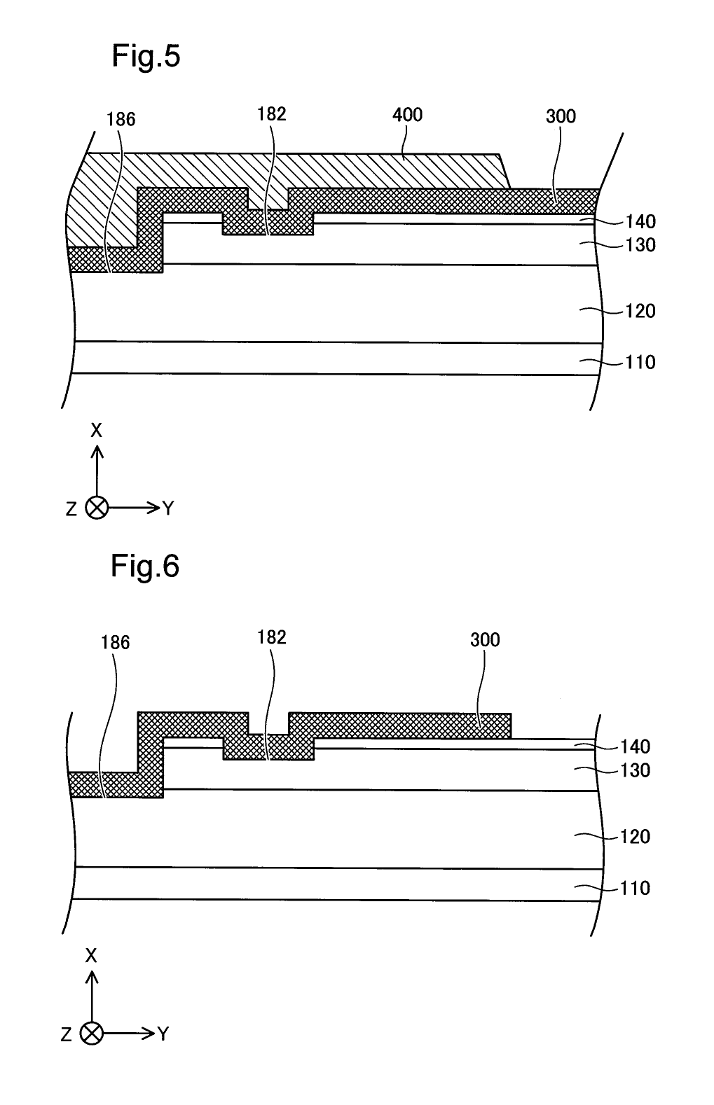

FIG. 5 is a cross sectional view illustrating the intermediate product of the semiconductor device 10 including the insulating film 300 and the photoresist 400 placed thereon.

The manufacturer subsequently etches the insulating film 300 according to the pattern of the photoresist and then removes the photoresist 400 (step P125). The etching technique employable in this step is at least one of dry etching and wet etching.

FIG. 6 is a cross sectional view illustrating the intermediate product of the semiconductor device 10 having the N-type semiconductor layer 140 partly exposed. This causes only an area for forming the trench 184 to be subjected to dry etching subsequently performed.

The manufacturer then performs dry etching to form the trench 184 (step P130). The conditions of dry etching employed in this embodiment may be, for example, plasma generating power of 100 W, bias power of 45 W and SiCl₄/Cl₂ gas flow ratio of 0.1. The invention is, however, not limited to these conditions. For example, Cl₂ and BCl₃ may be used as the etching gas.

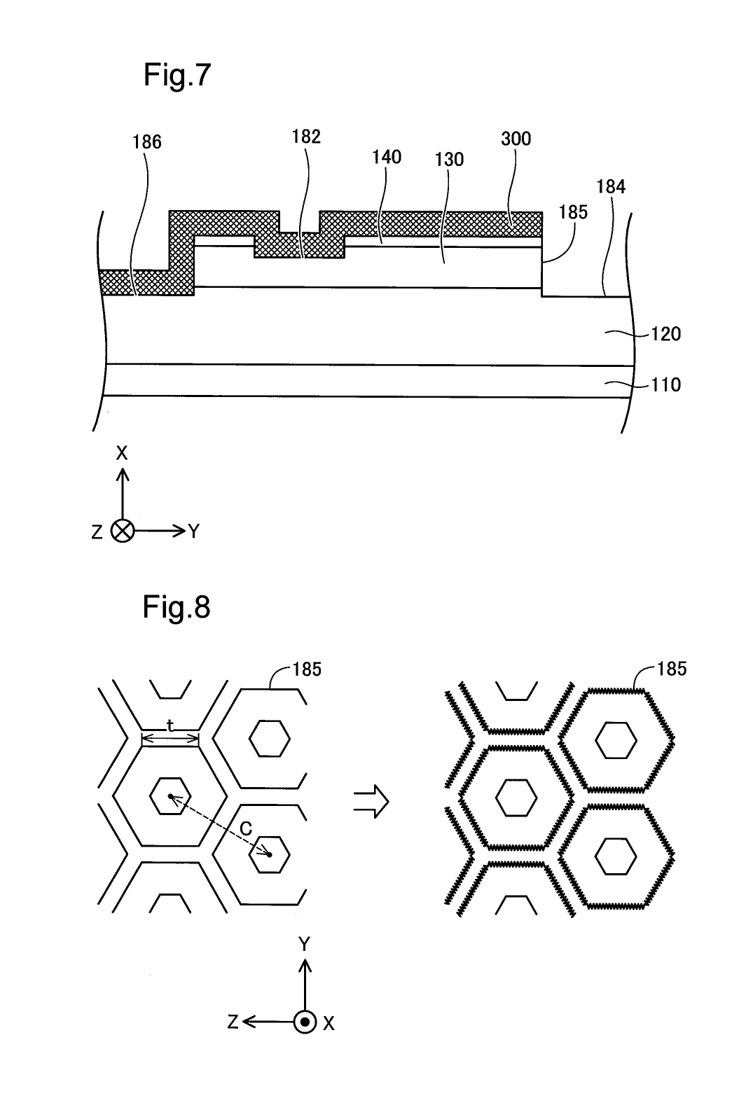

FIG. 7 is a cross sectional view illustrating the intermediate product of the semiconductor device 10 after dry etching. Dry etching should be performed, such that the side wall of the trench is at an angle of not less than 75 degrees and not greater than 105 degrees relative to the [11-20] axis. In terms of improving the electrical characteristics, the side wall of the trench is preferably at an angle of not less than 80 degrees and not greater than 100 degrees, more preferably at an angle of not less than 85 degrees and not greater than 95 degrees and furthermore preferably at an angle of not less than 88 degrees and not greater than 92 degrees relative to the [11-20] axis.

The manufacturer subsequently performs wet etching to form concavity/convexity on the side wall 185 of the trench 184 (step P135). The conditions of wet etching employed in this embodiment may be, for example, 22% TMAH (tetramethylammonium hydroxide) solution, etching temperature of 85 degrees and etching time of 30 minutes. The invention is, however, not limited to these conditions.

FIG. 8 is diagrams illustrating the intermediate product of the semiconductor device 10 in the states before and after wet etching. Unlike the illustration of, for example, FIG. 7, FIG. 8 illustrates the intermediate product of the semiconductor device 10 from the +X-axis direction. The left drawing of FIG. 8 illustrates the intermediate product before wet etching, and the right drawing of FIG. 8 illustrates the intermediate product after wet etching. As shown in FIG. 8, concavity/convexity is formed on the side wall 185 by wet etching. Formation of such concavity/convexity may be attributed to that (11-20) surface is more likely to be etched and the surfaces other than the (11-20) surface are exposed by wet etching.

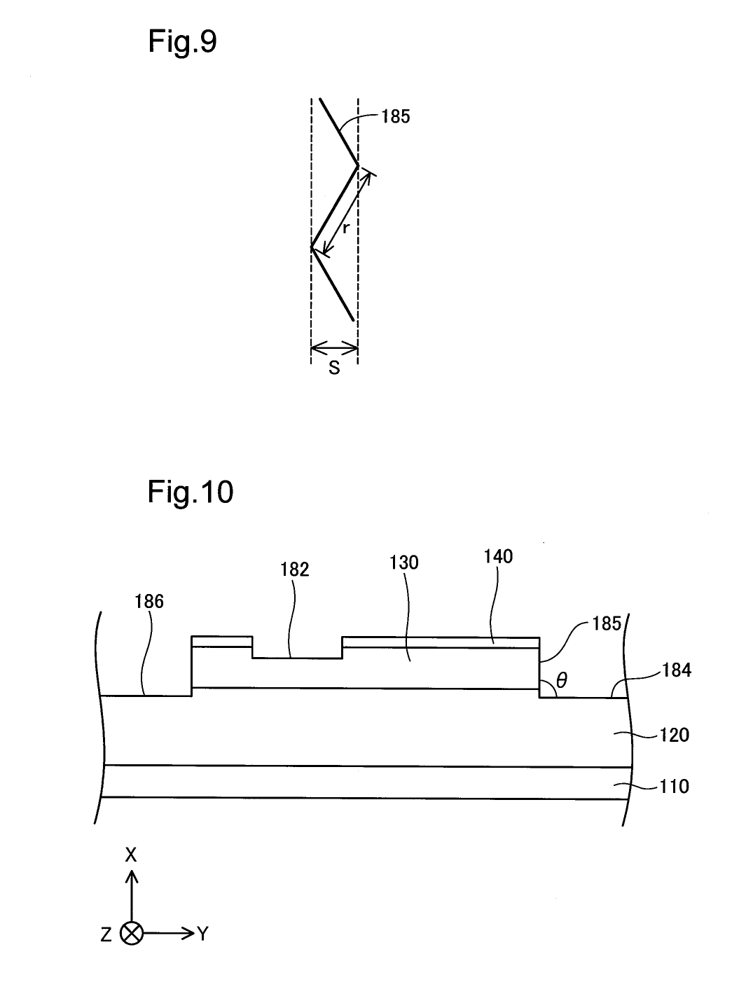

FIG. 9 is an enlarged view illustrating the side wall 185 of the trench 184. As shown in FIGS. 8 and 9, the side wall 185 has a width t in the longitudinal direction of the trench 184, a height S between a bottom of the concavity and a top of the convexity of the trench 184 and has a length r as the length of one side of the concavity/convexity.

The lower limit of the length r is preferably not less than 10 nm, is more preferably not less than 20 nm and is furthermore preferably not less than 30 nm. Controlling the lower limit of the length r in this range significantly increases the electric current, compared with the side wall 185 of the trench 184 without concavity/convexity. The upper limit of the length r is preferably not greater than 200 nm, is more preferably not greater than 100 nm and is furthermore preferably not greater than 70 nm. Controlling the upper limit of the length r in this range reduces the total area subjected to wet etching.

The height S is preferably not greater than 5% of the cell pitch of the semiconductor element. This allows for miniaturization design of the semiconductor element. The “height S” denotes a height between the bottom of the concavity and the top of the convexity. According to this embodiment, the “cell pitch” denotes a distance between adjacent semiconductor elements. The cell pitch is, for example, a distance C in FIG. 8. The height S preferably has a maximum value of not greater than 5% of the cell pitch of the semiconductor element and may not be necessarily constant.

FIG. 10 is a cross sectional view illustrating the intermediate product of the semiconductor device 10 after removal of the insulating film 300. In this state, the concavity/convexity is formed on the side wall 185 of the trench 184. An angle 8 of the side wall 185 relative to the bottom wall of the trench 184 after wet etching is preferably 90 degrees to 95 degrees. Controlling the angle of the side wall 185 to this range suppresses deterioration of breakdown voltage by the potential crowding and sufficiently removes the layer damaged by dry etching.

The manufacturer subsequently makes the insulating film 340 deposit on the entire surface of the intermediate product of the semiconductor device 10, forms contact holes in areas for forming the electrode 230 and the electrode 240, and then forms the electrode 230 and the electrode 240 (step P140).

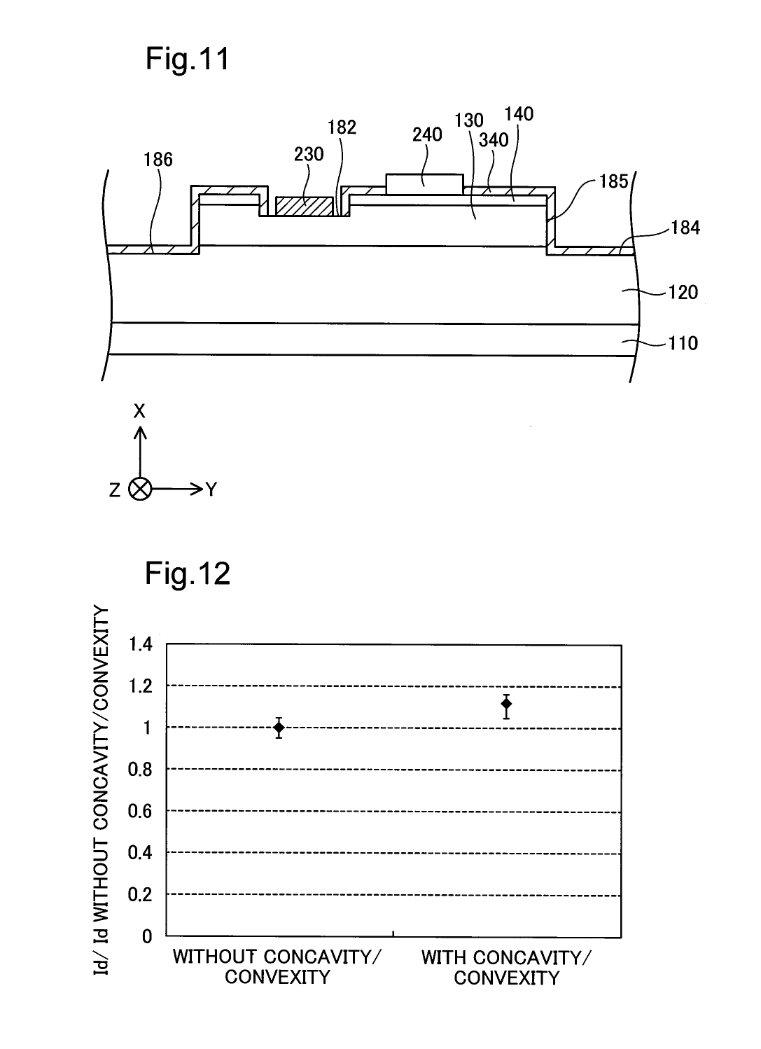

FIG. 11 is a cross sectional view illustrating the intermediate product of the semiconductor device 10 having the electrode 230 and the electrode 240 formed thereon.

After forming the electrodes 230 and 240, the manufacturer anneals the electrodes in order to reduce the contact resistances of the respective electrodes (step P145). The manufacturer then forms the electrode 250 in the trench 184 with the insulating film 340 placed thereon (step P150).

The manufacturer lastly forms the electrode 210 on the −X-axis direction side of the intermediate product of the semiconductor device 10 (step P155). This series of processes completes the semiconductor device 10 shown in FIG. 1.

### B. Performance Evaluation

FIG. 12 is a graph showing the ratio of Id to Id of a semiconductor device without concavity/convexity on the side wall 185 which is set equal to 1 as an average, in Id-Vg measurement of a semiconductor device with concavity/convexity on the side wall 185 and the semiconductor device without concavity/convexity on the side wall 185. In other words, this graph shows the relative value to the Id-Vg value of the semiconductor device without concavity/convexity on the side wall 185 of the trench 184, which is set equal to 1 as the average. The method employed for such measurement measures the value of electric current flowing through the electrode 250 under application of a specified voltage to the electrode 210 and the electrode 250. The semiconductor device without concavity/convexity on side wall is synonymous with the semiconductor device with flat side wall.

The semiconductor device with concavity/convexity in the trench 184 is the semiconductor device 10 manufactured by the manufacturing method described above. The semiconductor device without concavity/convexity in the trench 184 is manufactured by a manufacturing method similar to the manufacturing method of the semiconductor device 10 except that the surface exposed as the side wall 185 is (1-100) surface in the step of forming the trench 184 by dry etching, where the number of the measured samples is set to 8.

The result of FIG. 12 shows that the semiconductor device with concavity/convexity on the side wall 185 of the trench 184 has the larger electric current flowing through the electrode 250, compared with the semiconductor device without concavity/convexity on the side wall 185 of the trench 184. More specifically, the electric current flowing through the electrode 250 in the semiconductor device with concavity/convexity on the side wall 185 of the trench 184 is about 1.1 times as large as the electric current flowing through the electrode 250 in the semiconductor device without concavity/convexity on the side wall 185 of the trench 184. The reason of the increased electric current flowing through the electrode 250 by 1.1 times is attributed to that the surface area of the side wall 185 with concavity/convexity is about 1.1 times as large as the surface area of the side wall 185 without concavity/convexity, i.e., attributed to the greater gate width of the MOSFET.

### C. Modifications

The invention is not limited to the embodiment described above, but a multiplicity of variations and modifications may be made to the embodiment without departing from the scope of the invention. Some examples of possible modification are given below.

C1. Modification 1

The above embodiment uses silicon (Si) as the donor included in at least one of the substrate and the N-type semiconductor layer. The invention is, however, not limited to this embodiment. The donor used may be germanium (Ge) or oxygen (O).

C2. Modification 2

The above embodiment uses magnesium (Mg) as the acceptor included in the P-type semiconductor layer. The invention is, however, not limited to this embodiment. The acceptor used may be zinc (Zn) or carbon (C).

C3. Modification 3

The above embodiment uses the hexagonal semiconductor of gallium nitride as the semiconductor. The invention is, however, not limited to this embodiment. The semiconductor used may be another hexagonal semiconductor.

C4. Modification 4

In the embodiment described above, the electrode 230 as the body electrode is made of palladium (Pd). The invention is, however, not limited to this embodiment. The electrode 230 may be made of another material and may have a multi-layered structure. For example, the electrode 230 may be an electrode including at least one of conductive materials such as nickel (Ni), platinum (Pt) and cobalt (Co) and may have a two-layered structure of, for example, nickel (Ni)/palladium (Pd) or platinum (Pt)/palladium (Pd) (where palladium is on the semiconductor substrate side).

C5. Modification 5

In the embodiment described above, the electrode 250 as the gate electrode is made of aluminum (Al). The invention is, however, not limited to this embodiment. The electrode 250 may be made of polysilicon. The electrode 250 may be made of another material and may have a multi-layered structure. For example, the electrode 250 may have a two-layered structure of, for example, gold (Au)/nickel (Ni), aluminum (Al)/titanium (Ti), aluminum (Al)/titanium nitride (TiN) (where nickel, titanium or titanium nitride is on the gate insulating film side) or may have a three-layered structure of, for example, titanium nitride (TiN)/aluminum (Al)/titanium nitride (TiN).

C6. Modification 6

The surface area of the side wall of the trench with concavity/convexity according to the above embodiment is set to 1.1 times as large as the surface area of the side wall of the trench without concavity/convexity. The invention is, however, not limited to this embodiment. The surface area of the side wall of the trench with concavity/convexity may be 1.01 times or more and is preferably 1.1 times or more of the surface area of the side wall of the trench without concavity/convexity.

C7. Modification 7

The above embodiment uses MOSFET as the semiconductor device 10. The invention is, however, not limited to this embodiment. Available semiconductors other than MOSFET include a semiconductor having a trench gate, such as IGBT (insulated gate bipolar transistor).

C8. Modification 8

In the above embodiment, the electrode 230 as the body electrode and the electrode 240 as the source electrode are formed in the non-overlapping state. The invention is, however, not limited to this embodiment. The electrode 230 and the electrode 240 may be formed in at least partly overlapping state.

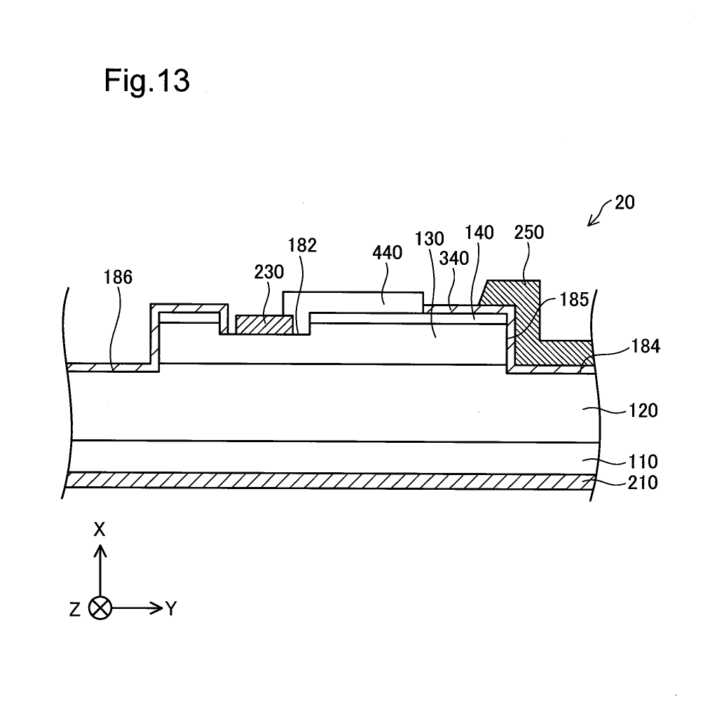

FIG. 13 is a cross sectional view illustrating a semiconductor device 20 having the electrode 230 as the body electrode and an electrode 440 as the source electrode formed in partly overlapping state. The semiconductor device 20 differs from the semiconductor device 10 by the shape of the source electrode but otherwise has the same structure. This configuration has no space between the electrode 230 and the electrode 440 and thereby shortens the overall length of the electrode 230 and the electrode 440.

The invention is not limited to the above embodiment or any of the above examples but may be implemented by any of various other configurations without departing from the scope of the invention. For example, the technical features of the embodiment or the examples corresponding to the technical features of the respective aspects described in Summary may be replaced or combined appropriately, in order to solve part or all of the problems described above or in order to achieve part or all of the advantageous effects described above. Any of the technical features may be omitted appropriately unless the technical feature is described as essential herein.

1. A semiconductor device using a hexagonal semiconductor, comprising:
a semiconductor substrate;
a first N-type semiconductor layer formed on the semiconductor substrate;
a P-type semiconductor layer formed on the first N-type semiconductor layer;
a second N-type semiconductor layer formed on the P-type semiconductor layer; and
a trench concaved to pass through the second N-type semiconductor layer and the P-type semiconductor layer and reach the first N-type semiconductor layer, wherein
the trench is arranged to have a longitudinal direction thereof at right angle ±15 degrees to an [11-20] axis and has concavity/convexity in a striped pattern formed on a side wall of the trench to be at right angle to a [0001] axis.

2. The semiconductor device according to claim 1, further comprising:
an electrode formed in the trench via an insulating film.

3. The semiconductor device according to claim 1,
wherein the semiconductor device is MOSFET.

4. The semiconductor device according to claim 1,
wherein each side of the concavity/convexity perpendicular to the [0001] axis has a length of not less than 10 nm and not greater than 200 nm.

5. The semiconductor device according to claim 1,
wherein the side wall of the trench with the concavity/convexity has a surface area of 1.1 times or more of a surface area of a side wall of a trench without the concavity/convexity.

6. The semiconductor device according to claim 1,
wherein the side wall of the trench has an angle of 90 degrees to 95 degrees relative to a bottom surface of the trench.

7. The semiconductor device according to claim 1,
wherein the concavity/convexity on the side wall of the trench has a height between a bottom of the concavity and a top of the convexity of 5% or less of a cell pitch.

8. The semiconductor device according to claim 1,
wherein the semiconductor is mainly made of gallium nitride.

9. A manufacturing method of a semiconductor device using a hexagonal semiconductor, the manufacturing method comprising:
providing an intermediate product of the semiconductor device having a semiconductor substrate, a first N-type semiconductor layer formed on the semiconductor substrate, a P-type semiconductor layer formed on the first N-type semiconductor layer, and a second N-type semiconductor layer formed on the P-type semiconductor layer;
patterning a photoresist on the second N-type semiconductor layer, such that a longitudinal direction of patterning is at right angle ±15 degrees to an [11-20] axis;
after the patterning, forming a trench concaved to pass through the second N-type semiconductor layer and the P-type semiconductor layer and reach the first N-type semiconductor layer by dry etching; and
after the forming the trench, forming concavity/convexity on a side wall of the trench by wet etching.
